(19) United States
(12) Patent Application Publication
(10) Pub. No.: US 2026/0080833 A1
(43) Pub. Date: Mar. 19, 2026

(54) DISPLAY DEVICE

(71) Applicant: LG Display Co., Ltd., Seoul (KR)

(72) Inventors: Ki Tae KWON, Gyeonggi-do (KR); Jong Wook JANG, Gyeonggi-do (KR); Dae Ho PARK, Gyeonggi-do (KR)

(21) Appl. No.: 19/273,839

(22) Filed: Jul. 18, 2025

(30) Foreign Application Priority Data
Sep. 13, 2024 (KR) 10-2024-0125868

(51) Int. Cl. G09G 3/3266

(52) U.S. Cl. CPC G09G 3/3266; G09G 2310/0289; G09G 2310/08; G09G 2320/0223; G09G 2320/0233; G09G 2330/023

(57) ABSTRACT

A display device includes a display panel including a first area and a second area in which a plurality of pixels are arranged; a plurality of gate drivers disposed in the first area and the second area; a first clock line connected to at least one first gate driver disposed in the first area; a second clock line connected to at least one second gate driver disposed in the second area; and a level shifter configured to generate a first clock signal and a second clock signal to be applied to each of the first clock line and the second clock line, respectively, wherein the first clock signal and the second clock signal have different voltage levels or gate-on times.

### CROSS-REFERENCE TO RELATED APPLICATION

Pursuant to 35 U.S.C. § 119(a), this application claims the benefit of an earlier filing date and right of priority to Korean Patent Application No. 10-2024-0125868, filed Sep. 13, 2024, the disclosure of which is incorporated herein by reference in its entirety.

### TECHNICAL FIELD

The present disclosure relates to display devices.

### BACKGROUND

Electroluminescent display devices are divided into inorganic light emitting display devices and organic light emitting display devices according to a material of a light emitting layer. An active-matrix type organic light emitting display device includes organic light emitting diodes (OLEDs) which emit light by themselves, and have advantages in that a response speed is fast and luminous efficiency, luminance, and a viewing angle are large.

In organic light-emitting display devices, organic light-emitting diodes (OLEDs) are formed in each of pixels. These organic light-emitting display devices not only respond quickly and have excellent light-emitting efficiency, luminance, and viewing angle, but also have excellent contrast ratio and color reproduction rate because they can express black tones as complete black.

### SUMMARY

A display device according to implementations of the present disclosure may include a display panel including a first area and a second area in which a plurality of pixels are arranged; a plurality of gate drivers disposed in the first area and the second area; a first clock line connected to the gate driver disposed in the first area; a second clock line connected to the gate driver disposed in the second area; and a level shifter configured to generate a first clock signal and a second clock signal to be applied to each of the first clock line and the second clock line, respectively, wherein the first clock signal and the second clock signal have different voltage levels or gate-on times.

A display device according to implementations of the present disclosure may include a display panel including a first area and a second area in which a plurality of pixels are arranged; a plurality of gate drivers disposed in the first area and the second area; and a timing controller configured to generate a first clock signal and a second clock signal to be respectively applied to gate drivers disposed in the first area and the second area, wherein the first clock signal and the second clock signal have different gate-on times.

A display device according to implementations of the present disclosure may include a display panel including a first area and a second area in which a plurality of pixels are arranged; a plurality of gate drivers disposed in the first area and the second area; and a level shifter configured to generate a first clock signal and a second clock signal to be respectively applied to gate drivers disposed in the first area and the second area, wherein the first clock signal and the second clock signal have different voltage levels.

### BRIEF DESCRIPTION OF THE DRAWINGS

The above and other objects, features, and advantages of the present disclosure will become clearer to those of ordinary skill in the art by describing exemplary implementations thereof in detail with reference to the attached drawings.

FIGS. 1A to 1B are block diagrams illustrating a display device according to an implementation of the present disclosure.

FIG. 2 is a diagram illustrating a shape of the display panel according to an implementation of the present disclosure;

FIG. 3 is a diagram illustrating a configuration of the gate driver shown in FIG. 2.

FIGS. 4A to 4C are diagrams for explaining the principle of applying a clock signal according to a comparative example.

FIGS. 5A to 5C are diagrams for explaining the principle of applying a clock signal according to a first implementation.

FIGS. 6A to 6D are diagrams for explaining the principle of applying a clock signal according to a second implementation.

FIGS. 7A to 7B are diagrams for explaining, as an example, the principle of applying a clock signal to a boundary region.

FIGS. 8A to 8B are diagrams for explaining, as another example, the principle of applying a clock signal to a boundary region.

### DETAILED DESCRIPTION

Display devices, for example, a liquid crystal display device or an organic light emitting display device, can include a display panel including a plurality of sub-pixels, a driver outputting a driving signal for driving the display panel, a power supply generating power to be supplied to the display panel or the driver, and the like.

To achieve a narrow bezel of a display panel, a gate driver that outputs gate signals is positioned between the pixels in the display area. However, depending on the display panel's shape, a delay may occur in the clock signal applied to the gate driver, which causes a delay in the gate signals output to the gate driver, resulting in luminance deviations depending on the area.

The present disclosure describes implementations that can address the above-described necessity and problems.

The present disclosure provides a display device that can improve luminance deviations between different areas of the display panel.

It should be noted that objects of the present disclosure are not limited to the above-described objects, and other objects of the present disclosure will be clear to those skilled in the art from the following descriptions.

According to the present disclosure, by dividing a display area of a display panel based on its shape, separating clock lines that apply clock signals to gate drivers disposed in the divided areas, and applying clock signals having different voltage levels or gate-on times through the separated clock lines, luminance deviations between the different areas may be alleviated.

According to the present disclosure, power consumption may be reduced depending on the areas, thereby enabling low-power operation of the display devices.

The effects of the present specification are not limited to the above-mentioned effects, and other effects that are not mentioned will be clearly understood by those skilled in the art from the following description and the appended claims.

Advantages and features of the present specification and methods of achieving them will become clear with reference to preferable implementations, which are described in detail, in conjunction with the accompanying drawings. However, the present specification is not limited to the implementations to be described below and may be implemented in different forms, the implementations are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the implementations of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted.

When ‘including,’ ‘having,’ ‘consisting,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

The same reference numerals may refer to substantially the same elements throughout the present disclosure.

The following implementations can be partially or entirely bonded to or combined with each other and can be linked and operated in technically various ways. The implementations can be carried out independently of or in association with each other.

Hereinafter, various implementations of the present disclosure will be described in detail with reference to the accompanying drawings.

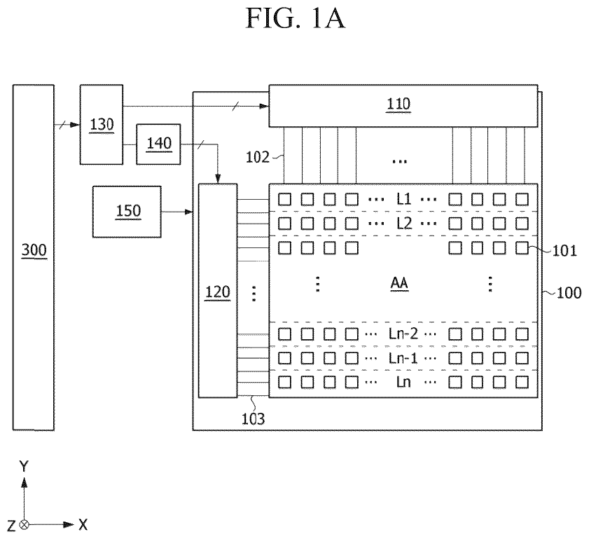

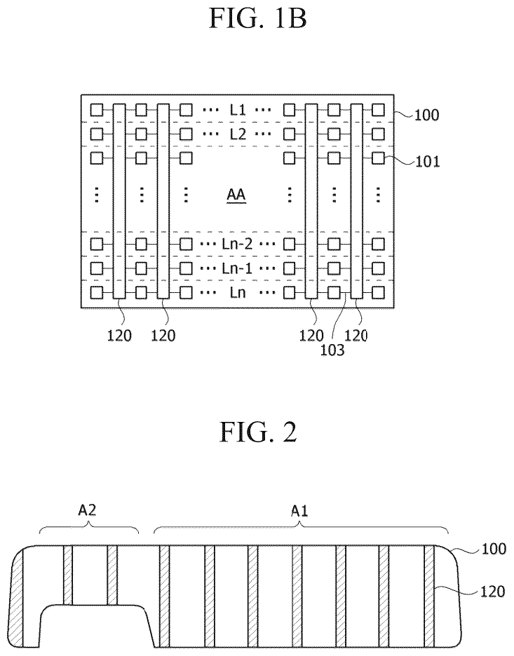

FIGS. 1A to 1B are block diagrams illustrating a display device according to an implementation of the present disclosure.

The display device according to an implementation of the present disclosure includes a display panel 100, and a display panel driving circuit for writing pixel data to pixels of the display panel 100. Additionally, the display device includes a power supply 150.

The display panel 100 may be, but is not limited to, a panel having a rectangular structure with a length in the X-axis direction, a width in the Y-axis direction, and a thickness in the Z-axis direction. For example, the display panel 100 may be a heterogeneous panel of which at least a portion is curved or elliptical.

The display area AA of the display panel 100 includes a pixel array to display an input image. The pixel array includes a plurality of data lines 102, a plurality of gate lines 103 crossing the data lines 102, and pixels arranged in a matrix form. The display panel 100 may further include power lines commonly connected to the pixels. The power lines may be commonly connected to pixel circuits to supply a voltage required for driving pixels 101 to the pixels 101.

Each of the pixels 101 may be divided into a red sub-pixel, a green sub-pixel, and a blue sub-pixel for color implementation. Each pixel may further include a white sub-pixel. Each sub-pixel includes a pixel circuit for driving a light emitting element. The light emitting element may include an OLED or an inorganic light emitting diode (LED). Each pixel circuit is connected to the data lines, the gate lines, and the power lines. In the following description, a pixel may be interpreted as a sub-pixel.

The display area AA includes a plurality of pixel lines L1 to Ln. Each of the pixel lines L1 to Ln includes one line of pixels arranged along the line direction (X-axis direction) in the pixel array of the display panel 100. Those pixels arranged in one pixel line share the same gate lines 103. The sub-pixels arranged in the column direction Y along the data line direction share the same data lines 102. One horizontal period is a time period obtained by dividing one frame period by the total number of pixel lines L1 to Ln.

The display panel 100 may be implemented with a non-transmissive display panel or a transmissive display panel. The transmissive display panel may be applied to a transparent display device in which an image is displayed on the screen and a real object in the background is visible. The display panel 100 may be made of a flexible display panel.

The power supply 150 receives an input voltage applied from a host system 300 and outputs a voltage needed to drive the pixels 101 of the display panel 100 and the display panel driving circuit. To this end, the power supply 150 may include a direct current to direct current converter (DC-DC converter). The DC-DC converter may include a charge pump, a regulator, a buck converter, a boost converter, and the like. The power supply 150 may output a constant voltage (or direct current voltage), such as gate-on voltage, gate-off voltage, pixel driving voltage, cathode voltage, reference voltage, IC driving voltage of the display panel driving circuit, through the DC-DC converter. The gate-on voltage and the gate-off voltage may be supplied to the level shifter 140 and the gate driver 120. Voltages such as pixel driving voltage, cathode voltage, and reference voltage may be supplied to the pixels 101 through the power lines commonly connected to the pixels 101.

The power supply 150 may further include a gamma voltage generator. The gamma voltage generator receives a high-potential reference voltage and a low-potential reference voltage and outputs a plurality of gamma reference voltages divided at specific intervals on a preset gamma curve, for example, a 2.2 gamma curve. The gamma reference voltages are supplied to the data driver 110. In the data driver 110, the gamma reference voltages are subdivided by a voltage dividing circuit into grayscale voltages. The gamma voltage generator may be implemented with a programmable gamma circuit that may adjust the voltage of each of the gamma reference voltages according to digital data. The timing controller 130, the host system 300, or a separate external device may update digital data stored in a register of the programmable gamma circuit through a communication interface.

The display panel driving circuit writes pixel data of the input image to the pixels 101 of the display panel 100 under the control of the timing controller 130. The display panel driving circuit includes a data driver 110 and a gate driver 120.

The display panel driving circuit may further include a touch sensor driver for driving touch sensors. The touch sensor driver is not shown in FIGS. 1A to 1B. The data driver 110 and the touch sensor driver may be integrated into one source drive IC.

The data driver 110 receives pixel data of the input image as a digital signal from the timing controller 130 and outputs a data voltage. The data driver 110 may receive gamma reference voltages and generate gamma compensation voltages for each grayscale through a voltage dividing circuit. The per-grayscale gamma compensation voltages are supplied to a digital to analog converter (hereinafter referred to as “DAC”) disposed in each channel of the data driver 110.

The data driver 110 samples and latches digital data received from the timing controller 130 and then inputs the digital data to the DAC. Here, the digital data includes pixel data of the input image. Additionally, the digital data may include mode selection data for selecting first mode and second mode. The DAC converts the pixel data into a gamma compensation voltage and outputs a data voltage of the pixel data.

The gate driver 120 may be formed on the display panel 100 together with the circuit elements and wiring lines of the display area AA. The gate driver 120 may be disposed in at least one of left and right non-display areas outside the display area AA in the display panel 100 or at least a part thereof may be disposed within the display area AA.

The gate driver 120 sequentially outputs pulses of the gate signals to the gate lines 103 under the control of the timing controller 130. The gate driver 120 may sequentially supply the gate signals to the gate lines 103 by shifting the pulses of the gate signals using shift registers. When a plurality of gate signals are applied to each pixel, the gate driver 120 may include a plurality of shift registers. The gate signal may include a scan signal being input to the pixel circuit through a plurality of gate lines, and an emission signal (or EM signal).

The gate driver 120 may be disposed in Gate In Panel (GIP) fashion in the non-display area, or in Gate in Active area (GIA) fashion between subpixels SP in the display area AA. For example, as shown in FIG. 1B, the circuit of the gate driver 120 may be located between the pixels 101 within the display area AA.

The timing controller 130 receives digital video data of an input image and a timing signal synchronized with this data from the host system 300. The timing signal may include a vertical synchronization signal Vsync, a horizontal synchronization signal Hsync, and a data enable signal DE. Since the vertical period and horizontal period may be known by counting the data enable signal DE, the vertical synchronization signal Vsync and the horizontal synchronization signal Hsync may be omitted. The horizontal synchronization signal Hsync and the data enable signal DE have a periodicity of 1 horizontal period (1H).

The timing controller 130 may control the display panel driving circuit by generating a data timing control signal for controlling the operation timing of the data driver 110 and a gate timing control signal for controlling the operation timing of the gate driver 120 based on the timing signals Vsync, Hsync, DE received from the host system 300. The timing controller 130 may synchronize the data driver 110 and the gate driver 120 by controlling the operation timing of the display panel driving circuit.

The gate timing control signal output from the timing controller 130 may be input to the shift register of the gate driver 120 through the level shifter 140. The level shifter 140 may convert a voltage of the gate timing control signal received from the timing controller 130 to a swing width between the gate-on voltage and the gate-off voltage and supply it to the gate driver 120.

The timing controller 130 may analyze the input image for each frame and generate a control signal for selectively outputting gate signals according to the analysis result. The generated control signal may be provided to the shift register of the gate driver 120 through the level shifter 140.

The host system 300 may include a main board of one of a television system, a set-top box, a navigation system, a personal computer (PC), a vehicle system, a mobile terminal, and a wearable terminal. The host system 300 may scale an image signal from a video source according to the resolution of the display panel 100, and may transmit it to the timing controller 130 together with the timing signals.

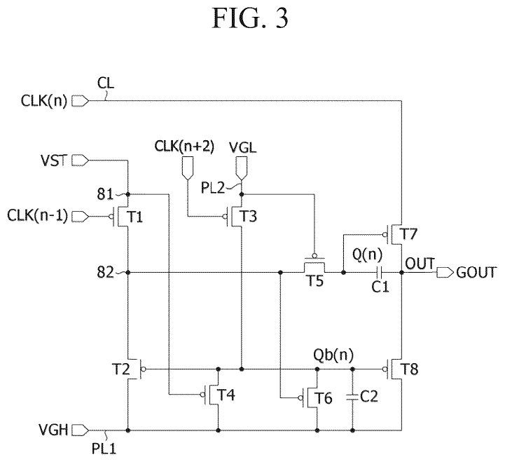

FIG. 2 is a diagram illustrating a shape of the display panel according to an implementation of the present disclosure, and FIG. 3 is a diagram illustrating a configuration of the gate driver shown in FIG. 2.

Referring to FIG. 2, the display panel according to an implementation of the present disclosure may have an irregular shape, such as a shape with varying length depending on position, rather than a rectangular shape. The display panel may include a first area A1 and a second area A2 in which the image is displayed, depending on its shape. The first area may be longer in the Y-axis direction than the second area.

The gate driver 120 may be formed along the column direction between the pixels, but are not necessarily limited thereto. For example, the gate driver 120 may be formed along the row direction between the pixels.

The gate driver 120 may include a scan driver that output a scan signal. The scan driver may output the scan signal based on a clock signal and a low potential voltage.

Referring to FIG. 3, the gate driver according to an implementation of the present disclosure may include a first transistor T1, a second transistor T2, a third transistor T3, a fourth transistor T4, a fifth transistor T5, a sixth transistor T6, a seventh transistor or pull-up transistor T7, an eighth transistor or pull-down transistor T8, a first capacitor C1, and a second capacitor C2.

The first transistor T1 is turned on by a previous clock signal CLK(n−1) and connects a first node 81 and a second node 82. The first transistor T1 includes a gate electrode to which the previous clock signal CLK(n−1) is applied, a first electrode connected to the first node 81, and a second electrode connected to the second node 82.

The second transistor T2 is turned on by the voltage from a second control node Qb(n) and connects a first power line PL1, to which a high potential voltage VGH is applied to the second node 82. The second transistor T2 includes a gate electrode connected to the second control node Qb(n), a first electrode connected to the second node 82, and a second electrode connected to the first power line PL1.

The third transistor T3 is turned on by a next clock signal CLK(n+2) and connects a second power line PL2, to which a low potential voltage VGL is applied, to the second control node Qb(n). The third transistor T3 includes a gate electrode to which the next clock signal CLK(n+2) is applied, a first electrode connected to the second power line PL2, and a second electrode connected to the second control node Qb(n)

The fourth transistor T4 is turned on by the voltage from the first node 81 and connects the second control node Qb(n) to the first power line PL1. The fourth transistor T4 includes a gate electrode connected to the first node 81, a first electrode connected to the second control node Qb(n), and a second electrode connected to the first power line PL1.

The fifth transistor T5 is turned on by a low potential voltage VGL and connects the second node 82 to a first control node Q(n). The fifth transistor T5 includes a gate electrode connected to the second power line PL2, a first electrode connected to the second node 82, and a second electrode connected to the first control node Q(n).

The sixth transistor T6 is turned on by the voltage from the second node 82 and connects the second control node Qb(n) to the first power line PL1. The sixth transistor T6 includes a gate electrode connected to the second node 82, a first electrode connected to the second control node Qb(n), and a second electrode connected to the first power line PL1.

The seventh transistor T7 is turned on by the voltage from the first control node Q(n) and outputs the low potential voltage VGL to an output node OUT. The seventh transistor T7 includes a gate electrode connected to the first control node Q(n), a first electrode connected to the clock line CL to which the clock signal CLK(n) is applied, and a second electrode connected to the output node OUT.

The eighth transistor T8 is turned on by the voltage from the second control node Qb(n) and outputs the high potential voltage VGH to the output node OUT. The eighth transistor T8 includes a gate electrode connected to the second control node Qb(n), a first electrode connected to the output node OUT, and a second electrode connected to the first power line PL1.

The first capacitor C1 is connected between the gate electrode and the second electrode of the seventh transistor T7. The second capacitor C2 is connected between the gate electrode and the second electrode of the eighth transistor T8.

Because the gate driver outputs the gate signal based on the clock signal and the low potential voltage, any delay in the clock signal may cause a delay in the gate signal.

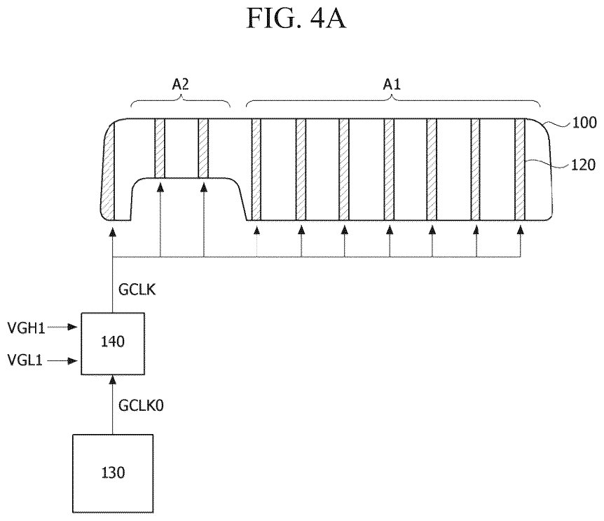

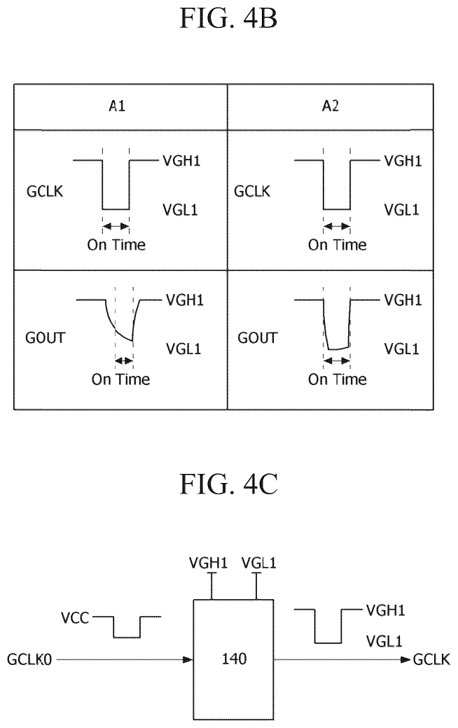

FIGS. 4A to 4C are diagrams for explaining the principle of applying a clock signal according to a comparative example.

Referring to FIGS. 4A to 4C, in a comparative example, a clock signal GCLK may be generated using the timing controller 130 and the level shifter 140. In other words, the timing controller 130 may generate a clock signal GCLK0 having a first voltage level VCC and apply the clock signal to the level shifter 140.

The level shifter 140 may generate the clock signal GCLK having a second voltage level, namely a gate-on voltage VGH1 and a gate-off voltage VGL1, from the clock signal GCLK0 having the first voltage level, and then apply the clock signal GCLK to all gate drivers of the first area A1 and the second area A2 in the display panel.

The clock signal GCLK is applied equally to all gate drivers in the first area A1 and the second area A2. Because the lengths of the wires through which the clock signal is applied vary depending on the areas, the RC delay varies. For example, the RC delay in the first area A1 is greater than that in the second area A2. Consequently, a delay in the clock signal GCLK occurs depending on the areas, which leads to a delay in the gate signal GOUT, resulting in variations in gate-on time and causing luminance deviation. Specifically, since the gate-on time of the gate signal GOUT in the first area A1 is shorter than that in the second region A2, the luminance in the first area is relatively lower.

Therefore, implementations propose measures to improve the delay deviation in the clock signal.

In a first implementation, it is intended to separate the clock lines to which the clock signal is applied depending on the areas, and apply clock signals having different voltage levels through the separated clock lines, respectively.

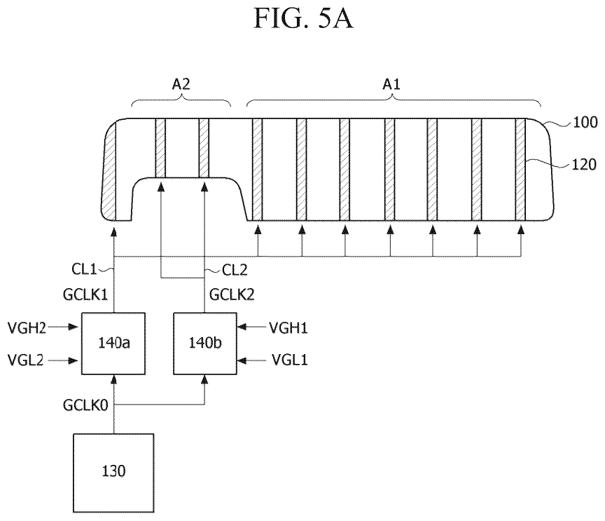

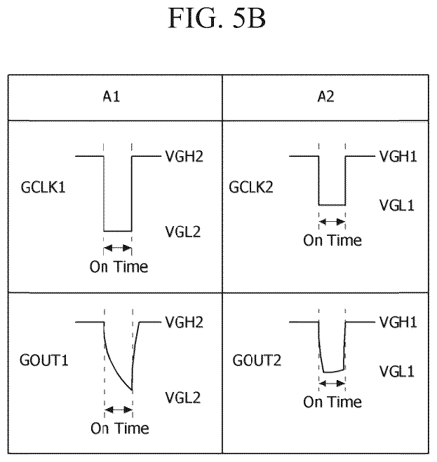

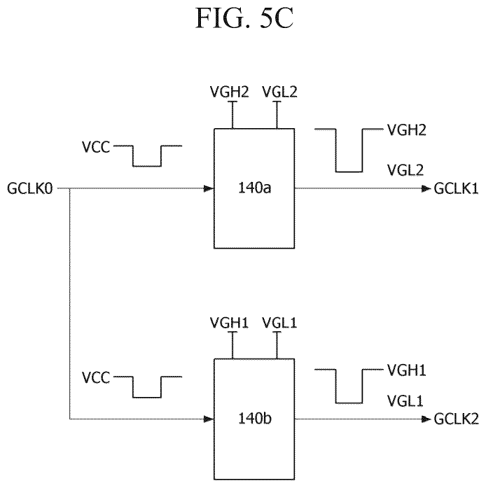

FIGS. 5A to 5C are diagrams for explaining the principle of applying a clock signal according to a first implementation.

Referring to FIGS. 5A to 5C, the first implementation may generate clock signals GCLK1 and GCLK2 having different voltage levels depending on the areas using the timing controller 130 and the level shifter 140. Specifically, the timing controller 130 may generate the clock signal GCLK0 having the first voltage level VCC and apply the clock signal to a first level shifter 140a and a second level shifter 140b.

The first level shifter 140a may generate a first clock signal GCLK1 having a second voltage level, i.e., a second gate-on voltage VGH2 and a second gate-off voltage VGL2, from the clock signal GCLK0 having a first voltage level, and apply the generated first clock signal GCLK1 to all gate drivers in the first area A1 of the display panel through a first clock line CL1.

The second level shifter 140b may generate the second clock signal GCLK2 having a second voltage level, i.e., a first gate-on voltage VGH1 and a first gate-off voltage VGL1, from the clock signal GCLK0 having a first voltage level, and apply the generated second clock signal GCLK2 to all gate drivers in the second area A2 of the display panel through a second clock line CL2.

Here, the gate-on voltages are set such that the second gate-on voltage VGH2>the first gate-on voltage VGH1, and the gate-off voltages are set such that the second gate-off voltage VGL2<the first gate-off voltage VGL1.

By applying the first clock signal GCLK1 having VGH2 and VGL2 to the first area A1 and the second clock signal GCLK2 having VGH1 and VGL1 to the second area A2, the gate-on time deviation in the gate signal output from the gate driver in each area A1, A2 may be alleviated.

In the first implementation, the gate-on voltage of the clock signal applied to an area with relatively high RC delay is increased, and the gate-off voltage is decreased, but the implementation is not necessarily limited thereto. For example, the gate-on voltage of the clock signal applied to an area with relatively low RC delay may be decreased, and the gate-off voltage may be increased.

Data showing the results of improving the luminance deviation between the areas is shown in Table 1 below.

TABLE 1

Category

| | |
|---|---|
| Comparative Example | Implementation |

Areas

| | A1 | | A2 | | A1 | | A2 | |
|---|---|---|---|---|---|---|---|---|
| VGL | −15.0 | V | −15.0 | V | −15.5 | V | −15.0 | V |
| 63Gray | 27.1 | nit | 25.6 | nit | 25.6 | mit | 25.6 | nit |
| 31Gray | 5.7 | nit | 5.2 | nit | 5.2 | nit | 5.2 | nit |

As shown in Table 1 above, it may be seen that in the comparative example where the same clock signal is applied to all of the areas, there is luminance variation between the areas, whereas in the implementation, the luminance variation between the areas is alleviated.

In a second implementation, it is intended to separate the clock lines to which a clock signal is applied depending on the areas, and to apply clock signals having different gate-on times through the separated clock lines, respectively.

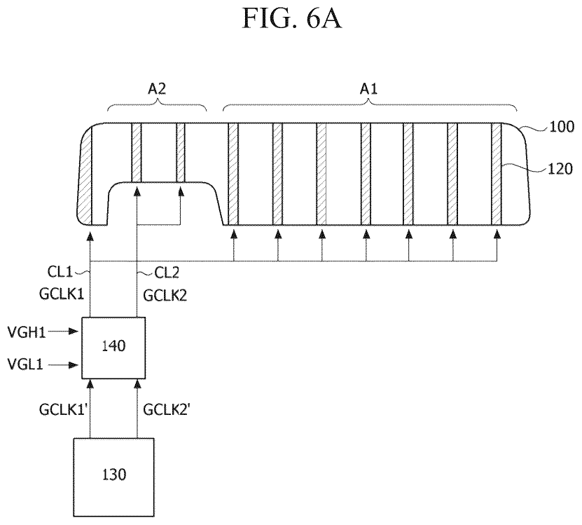

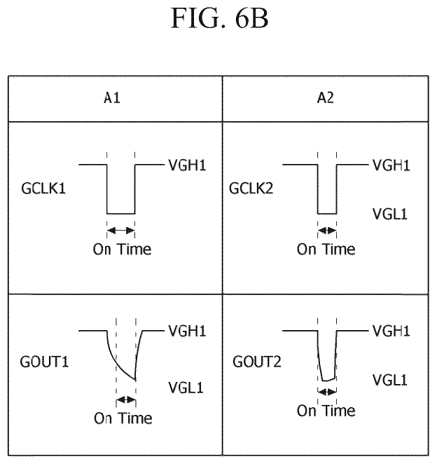

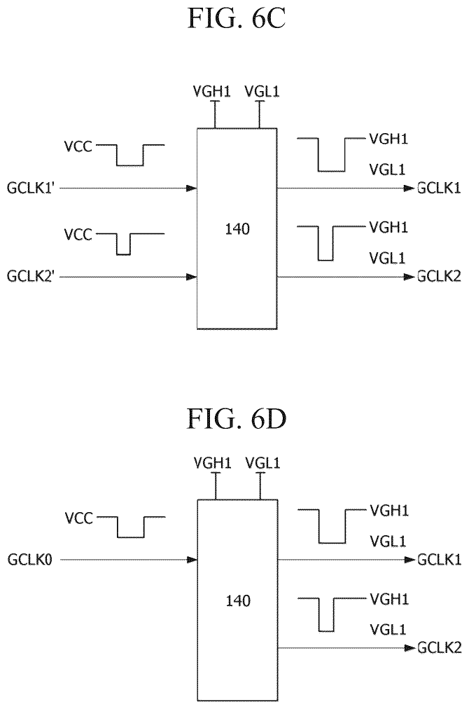

FIGS. 6A to 6D are diagrams for explaining the principle of applying a clock signal according to a second implementation.

Referring to FIGS. 6A to 6C, the second implementation may generate clock signals GCLK1 and GCLK2 having different gate-on times depending on the areas using the timing controller 130 and the level shifter 140. Specifically, the timing controller 130 may generate clock signals GCLK1′ and GCLK2′ having different gate-on times of the first voltage level VCC and apply them to the level shifter 140.

Here, the clock signal GCLK2′ may be generated with a shorter gate-on time than that of the clock signal GCLK1′.

The level shifter 140 generates a first clock signal GCLK1 and a second clock signal GCLK2 having the second voltage level, i.e., a gate-on voltage VGH1 and a gate-off voltage VGL1, from the clock signals GCLK1′ and GCLK2′ having different gate-on times of the first voltage level VCC, respectively, may apply the generated first clock signal GCLK1 to all gate drivers in the first area A1 of the display panel through a first clock line CL1, and may apply the generated second clock signal GCLK2 to all gate drivers in the second area A2 of the display panel through a second clock line CL2.

Here, the timing controller generates the clock signals having different gate-on times, but is not limited thereto. For example, the clock signals having different gate-on times may be generated by the level shifter.

Referring to FIG. 6D, the timing controller 130 may generate the clock signal GCLK0 having the first voltage level VCC and apply the clock signal to the level shifter 140.

The level shifter 140 may generate the first clock signal GCLK1 and the second clock signal GCLK2 having different gate-on times of the second voltage level, i.e., a gate-on voltage VGH1 and a gate-off voltage VGL1, from the clock signal GCLK0 having the first voltage level VCC, may apply the generated first clock signal GCLK1 to all gate drivers in the first area A1 of the display panel through a first clock line CL1, and may apply the generated second clock signal GCLK2 to all gate drivers in the second area A2 of the display panel through a second clock line CL2.

By applying the first clock signal GCLK1 having a first gate-on time to the first area A1 and the second clock signal GCLK2 having a second gate-on time to the second area A2, the gate-on time deviation in the gate signal output from the gate driver of each area A1, A2 may be alleviated.

In the second implementation, the gate-on time of the clock signal applied to an area with relatively high RC delay is increased, but the implementation is not necessarily limited thereto. For example, the gate-on time of the clock signal applied to an area with relatively low RC delay may be decreased.

Furthermore, in the implementation of the present disclosure, it is intended to slightly adjust the voltage level or the gate-on time of the clock signal in a boundary region where the first area A1 and the second area A2 are adjacent to each other.

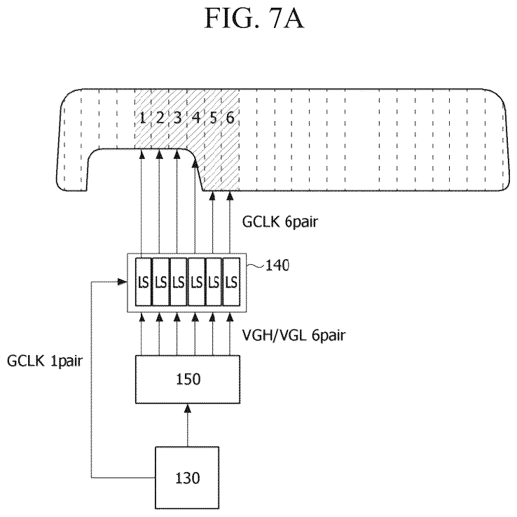

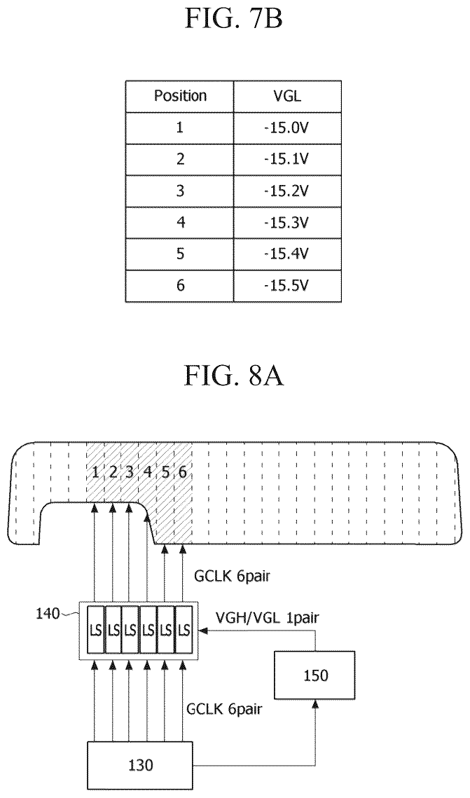

FIGS. 7A to 7B are diagrams for explaining, as an example, the principle of applying a clock signal to a boundary region.

Referring to FIG. 7A to FIG. 7B, in the implementation of the present disclosure, a boundary region where the first area A1 and the second area A2 are adjacent to each other may be divided into a plurality of boundary areas, and clock signals having different voltage levels may be applied to the gate drivers disposed in each of the plurality of boundary areas.

For example, the boundary region may be divided into first to sixth boundary areas 1, 2, 3, 4, 5, and 6, and clock signals having six pairs of voltage levels may be applied to the separated first to sixth boundary areas 1, 2, 3, 4, 5, and 6 through six pairs of clock lines, respectively.

The second clock signal GCLK2 having the voltage level applied to the second area A2 is applied to the first boundary area 1, and the first clock signal GCLK1 having the voltage level applied to the first area A1 is applied to the sixth boundary area 6.

Clock signals having voltage levels between the voltage level of the second clock signal GCLK2 and the voltage level of the first clock signal GCLK1 are applied to the second to fifth boundary areas 2, 3, 4, and 5. For example, clock signals having voltage levels between the gate-on voltage VGH or the gate-off voltage VGL of the second clock signal GCLK2 and the first clock signal GCLK1 may be applied.

A clock signal with a gate-off voltage VGL of −15.0 V is applied to the first boundary area 1. A clock signal with a gate-off voltage VGL of −15.1 V is applied to the second boundary area 2. A clock signal with a gate-off voltage VGL of −15.2 V is applied to the third boundary area 3. A clock signal with a gate-off voltage VGL of −15.3 V is applied to the fourth boundary area 4. A clock signal with a gate-off voltage VGL of −15.4 V is applied to the fifth boundary area 5. A clock signal with a gate-off voltage VGL of −15.5 V is applied to the sixth boundary area 6.

In this implementation, the voltage levels of the clock signals to be applied to the first to sixth boundary areas 1, 2, 3, 4, 5, and 6 may be generated to increase or decrease by a constant magnitude.

That is, the timing controller 130 generates a clock signal having the first voltage level and applies it to the level shifter 140.

The level shifter 140 may include six level shifters LS, and each of the six level shifters LS may generate clock signals having voltage levels based on pairs of different gate-on voltage VGH and gate-off voltage VGL from the clock signal having the first voltage level.

The power supply 150 may supply pairs of different gate-on voltage VGH and gate-off voltage VGL to the six level shifters LS included in the level shifter 140, respectively.

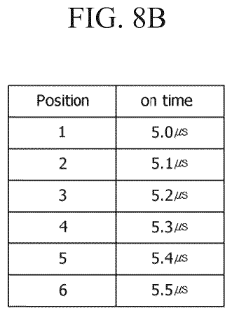

FIGS. 8A to 8B are diagrams for explaining, as another example, the principle of applying a clock signal to a boundary region.

Referring to FIGS. 8A and 8B, in an implementation of the present disclosure, a boundary region where the first area A1 and the second area A2 are adjacent to each other may be divided into a plurality of boundary areas, and clock signals having different gate-on times may be applied to the gate drivers disposed in each of the plurality of boundary areas. Here, some of the gate drivers disposed in each boundary area may be configured to apply gate signals to the pixels in the first area A1 and some other gate drivers may be configured to apply gate signals to the pixels in the second area A2, but the configuration is not necessarily limited thereto.

For example, the boundary region may be divided into first to sixth boundary areas 1, 2, 3, 4, 5, and 6, and clock signals having six pairs of gate-on times may be applied to the separated first to sixth boundary areas 1, 2, 3, 4, 5, and 6 through six pairs of clock lines, respectively.

The second clock signal GCLK2 having the gate-on time applied to the second area A2 is applied to the first boundary area 1, and the first clock signal GCLK1 having the gate-on time applied to the first area A1 is applied to the sixth boundary area 6.

Clock signals having gate-on times between the gate-on time of the second clock signal GCLK2 and the gate-on time of the first clock signal GCLK1 are applied to the second to fifth boundary areas 2, 3, 4, and 5.

A clock signal with a gate-on time of 5.0 μs is applied to the first boundary area 1. A clock signal with a gate-on time of 5.1 μs is applied to the second boundary area 2. A clock signal with a gate-on time of 5.2 μs is applied to the third boundary area 3. A clock signal with a gate-on time of 5.3 μs is applied to the fourth boundary area 4. A clock signal with a gate-on time of 5.4 μs is applied to the fifth boundary area 5. A clock signal with a gate-on time of 5.5 μs is applied to the sixth boundary area 6.

In this implementation, the gate-on times of the clock signals to be applied to the first to sixth boundary areas 1, 2, 3, 4, 5, and 6 may be generated to increase or decrease by a constant magnitude.

In one example, the timing controller 130 generates clock signals having different gate-on times of the first voltage level and applies them to the level shifter 140. The level shifter 140 may generate clock signals having second voltage levels, namely a gate-on voltage VGH and a gate-off voltage VGL, from the clock signals having different gate-on times provided from the timing controller 130.

In another example, the timing controller 130 generates clock signals having first voltage levels and applies them to the level shifter 140. The level shifter 140 may generate clock signals having second voltage levels, i.e., different gate-on times of the gate-on voltage VGH and the gate-off voltage VGL, from the clock signal having the first voltage level applied from the timing controller 130.

In this case, the power supply 150 may supply predetermined gate-on voltage VGH and gate-off voltage VGL to the level shifter 140 under the control of the timing controller 130.

Although the implementations of the present disclosure have been described in more detail with reference to the accompanying drawings, the present disclosure is not limited thereto and may be embodied in many different forms without departing from the technical concept of the present disclosure. Therefore, the implementations disclosed in the present disclosure are provided for illustrative purposes only and are not intended to limit the technical concept of the present disclosure. The scope of the technical concept of the present disclosure is not limited thereto. Therefore, it should be understood that the above-described implementations are illustrative in all aspects and do not limit the present disclosure.

What is claimed is:

1. A display device comprising:
a display panel including a first area and a second area in which a plurality of pixels are arranged;
a plurality of gate drivers, wherein the plurality of gate drivers comprise at least one first gate driver disposed in the first area and at least one second gate driver disposed in the second area;
a first clock line connected to the at least one first gate driver disposed in the first area;
a second clock line connected to the at least one second gate driver disposed in the second area; and
a level shifter configured to generate a first clock signal and a second clock signal to be applied to each of the first clock line and the second clock line, respectively,
wherein the first clock signal and the second clock signal have different voltage levels or gate-on times.

2. The display device of claim 1, wherein the first area and the second area are divided according to a shape of the display panel, and
wherein a length of the second area over which the second clock signal is applied is shorter compared to a length of the first area over which the first clock signal is applied.

3. The display device of claim 1, wherein the level shifter includes a first level shifter and a second level shifter, and
the first level shifter generates the first clock signal having a first gate-on voltage and a first gate-off voltage, and
the second level shifter generates the second clock signal having a second gate-on voltage and a second gate-off voltage.

4. The display device of claim 3, wherein the first gate-on voltage is higher than the second gate-on voltage, and
the first gate-off voltage is lower than the second gate-off voltage.

5. The display device of claim 1, further comprising:
a timing controller configured to generate the first clock signal having a first gate-on time and the second clock signal having a second gate-on time,
wherein the level shifter is configured to:
apply the first clock signal having the first gate-on time to the first clock line, and
apply the second clock signal having the second gate-on time to the second clock line.

6. The display device of claim 5, wherein the second gate-on time is set to be shorter than the first gate-on time.

7. The display device of claim 1, further comprising:
a timing controller configured to generate at least one clock signal having a predetermined voltage level,
wherein, based on the at least one clock signal generated by the timing controller, the level shifter is configured to:
generate the first clock signal having a first gate-on time and the second clock signal having a second gate-on time,
apply the first clock signal having the first gate-on time to the first clock line, and
apply the second clock signal having the second gate-on time to the second clock line.

8. The display device of claim 1, wherein the display panel includes a plurality of boundary areas adjacent to a boundary between the first area and the second area, and
wherein a plurality of clock signals applied to the plurality of boundary areas are set to differ by a predetermined magnitude in their voltage levels or gate-on times.

9. A display device comprising:
a display panel including a first area and a second area in which a plurality of pixels are arranged;
a plurality of gate drivers, wherein the plurality of gate drivers comprise at least one first gate driver disposed in the first area and at least one second gate driver disposed in the second area; and
a timing controller configured to generate a first clock signal and a second clock signal to be respectively applied to the at least one first gate driver disposed in the first area and the at least one second gate driver disposed in the second area,
wherein the first clock signal and the second clock signal have different gate-on times.

10. The display device of claim 9, wherein the second clock signal has a shorter gate-on time than the first clock signal.

11. The display device of claim 9, wherein the display panel includes a plurality of boundary areas adjacent to a boundary between the first area and the second area, and
wherein a plurality of clock signals applied to the plurality of boundary areas are set differently between gate-on times of the first clock signal and the second clock signal.

12. A display device comprising:
a display panel including a first area and a second area in which a plurality of pixels are arranged;
a plurality of gate drivers, wherein the plurality of gate drivers comprise at least one first gate driver disposed in the first area and at least one second gate driver disposed in the second area; and
a level shifter configured to generate a first clock signal and a second clock signal to be respectively applied to the at least one first gate driver disposed in the first area and the at least one second gate driver disposed in the second area,
wherein the first clock signal and the second clock signal have different voltage levels.

13. The display device of claim 12, wherein the second clock signal has a voltage level less than that of the first clock signal.

14. The display device of claim 13, further comprising:
a power supply configured to supply a gate-on voltage and a gate-off voltage to the level shifter,
wherein the first clock signal has the gate-on voltage higher than that of the second clock signal, and the first clock signal has the gate-off voltage lower than that of the second clock signal.

15. The display device of claim 12, wherein the display panel includes a plurality of boundary areas adjacent to the boundary between the first area and the second area, and
wherein a plurality of clock signals applied to the plurality of boundary areas are set differently between voltage levels of the first clock signal and the second clock signal.
